(19) United States
(12) Patent Application Publication
(10) Pub. No.: US 2012/0315710 A1
(43) Pub. Date: Dec. 13, 2012

(54) METHOD FOR PRODUCING RECONSTITUTED WAFERS AND METHOD FOR PRODUCING SEMICONDUCTOR DEVICES

(76) Inventors: Kazuyuki Hozawa, Hachioji (JP); Kenichi Takeda, Higashimurayama (JP); Mayu Aoki, Kokubunji (JP)

(21) Appl. No.: 13/578,341

(22) PCT Filed: Feb. 1, 2011
(86) PCT No.: PCT/JP2011/052047

§ 371 Date: Aug. 10, 2012

(30) Foreign Application Priority Data
Mar. 4, 2010 (JP) 2010-047787

(51) Int. Cl. H01L 21/82; H01L 21/66

(52) U.S. Cl. 438/5; 438/109; 257/E21.529; 257/E21.602

(57) ABSTRACT

In order to provide a method for producing semiconductor devices that can use the highly productive W to W method, and achieve a high yield, a method for producing semiconductor devices comprises a step (S401) in which a reconstituted wafer is prepared by replacing defective chips with non-defective chips, a step (S403) in which the reconstituted wafer and the base wafer are connected to one another by laminating, a step (S406) in which through-electrodes are formed in the reconstituted wafer, and a step (S409) in which a separate reconstituted wafer is laminated onto and connected to the reconstituted wafer having through-electrodes.

### TECHNICAL FIELD

The present invention relates to a method for producing semiconductor devices, the method including stacking substrates (wafers) with a plurality of semiconductor elements (chips) formed thereon.

### BACKGROUND ART

In recent years, demands for miniaturization, weight reduction, high performance and low power consumption of electronic equipment has been growing. These demands can be satisfied by making the geometry of semiconductor devices finer and thinner; however, this geometric reduction technique is approaching its physical limits.

As finer semiconductor processes approach the physical limits, the development speed toward finer semiconductor devices has slowed down and the manufacturing cost of cutting-edge products significantly increases. Thus, higher performance and lower power consuming semiconductor devices are becoming more difficult to achieve.

As a method for achieving all of the demands, i.e., miniaturization, weight reduction, high performance and low power consumption, for semiconductor devices without recourse to the finer semiconductor processes, three-dimensional stacking technology in which semiconductor devices having through-hole electrodes (through electrodes) formed therein are three-dimensionally stacked on top of one another has been actively studied and developed. In comparison with conventional two-dimensional packaging technology and multi-layer stacking technology of semiconductor devices with wire bonding, the technology for three-dimensionally stacking semiconductor devices with through-hole electrodes on top of one another enables not only extremely shortened wiring distances and tremendous reduction in wiring resistance and wiring capacitance, but also new circuitry technology development which has been impossible by conventional technologies.

Generally, semiconductor wafer bonding includes stacking wafers with defective chips on top of one another and connecting the stacked wafers. In this case, the yield of the wafer stack decreases depending on the defective-chip ratio of the semiconductor wafers and the number of the stacked wafers, and therefore it is very important to explore how the high yields of the wafer stack can be maintained.

Three-dimensional stacking technology is disclosed, for example, in PTL 1 and NPTL 1.

### CITATION LIST

### Patent Literature

PTL 1: Japanese Patent Application Laid-Open Publication No. 2001-308116

### Non Patent Literature

NPTL 1: NIKKEI MICRODEVICES, August, 2007, p44-53

### SUMMARY OF INVENTION

### Technical Problem

General semiconductor wafers are produced at a yield of less than 100%; the yield is low in an early stage of volume production; and the yield mostly remains at 80% to 95% even after the volume production is stabilized. Table 1 shows the relationship between the yield of initial wafers and the yield of multi-layer (laminated) chips.

TABLE 1

| | |
|---|---|
| Initial | |
| wafer | Multi-Layer Chip Yield |

| yield | 2 layers | 5 layers | 10 layers | 30 layers |
|---|---|---|---|---|
| 98% | 96 | 90 | 82 | 55 |
| 95% | 90 | 77 | 60 | 21 |
| 90% | 81 | 59 | 35 | 4 |
| 85% | 72 | 44 | 20 | 1 |
| 80% | 64 | 33 | 11 | 0 |

As shown in Table 1, for example, if five wafers with a yield of 80% are stacked on top of one another, the ultimate yield of the five-wafer stack falls 33% by a simple calculation, but the actual yield is estimated to be on the order of 20% in consideration of the yield reduction occurring during wafer bonding. The problem underlying the assumption is that the remaining good chips, about 50% to 60%, are waste.

Especially, the yields at early stages of volume production tend to be low, and therefore the yield significantly decreases to bond even two wafers. It can be said that it is inappropriate to perform wafer bonding at the early stages of volume production.

Since the yield significantly drops as the number of the wafers to be stacked on top of one another (W to W: Wafer to Wafer) increases as described above, wafer bonding is not performed in many cases for the purpose of yield enhancement. For example, NPTL 1 discloses a method for sorting good chips from defective chips on a wafer and, after singulation of the chips, stacking only the good chips (C to C: chip to chip). However, the method has very poor productivity because the chips need to be stacked one by one. When through-hole electrodes (or through-silicon vias, TSVs), bumps and so on are formed on the singulated chips and in turn the chips are stacked on top of one another, a specialized machine to form the TSVs and bumps on the chips is needed, which is an additional capital investment for only chips.

A method providing more productivity than the C to C method is stacking separately singulated good chips on previously detected good chips present on another wafer (C to W: Chip to Wafer). The wafer on which the singulated good chips are stacked is not limited to a Si wafer, but may be a transparent substrate such as glass. Actually, PTL 1 shows a method for simultaneously processing a plurality of good chips affixed on a glass substrate.

However, general C to W methods indispensably require a technique to accurately align and connect the good chips with the previously detected good chip areas on the wafer, and therefore the processing time increases proportionately with the number of chips to be aligned and the alignment accuracy level. Similarly, an increase in the number of the chips to be stacked imposes more heat loads on the support substrate to be a base or the firstly placed chips. These issues become more serious as the area of the chips decreases and the number of chips to be stacked increases; in short, stacking more layers increase disadvantages. In addition, heavy heat loads cause a high possibility of faulty connection, chip warpage and other problems. For very thin chips having projections such as bumps, a handling mechanism capable of dealing with chip warpage and bump roughness is needed. Since a typical handling mechanism is not intended to handle badly-warped chips and rough surface chips with bumps, it is very difficult to deal with extremely thin chips with bumps formed on both sides.

The present invention has an object to provide a semiconductor device producing method that uses a highly-productive W to W bonding process and achieves high yields.

### Solution to Problem

In an embodiment to achieve the object, the method for producing a semiconductor device includes the steps of: preparing a reconstituted wafer fabricated through a method for producing a reconstituted wafer; and stacking the reconstituted wafer and a semiconductor wafer or a substrate. The method for producing a reconstituted wafer includes the steps of: preparing a semiconductor wafer with a plurality of semiconductor chips formed thereon; conducting a test on the semiconductor wafer to identify good chips; removing defective chip areas including defective chips from the semiconductor wafer; and placing good chips extracted from another semiconductor wafer in the removed defective chip areas.

In addition, the method for producing a semiconductor device includes the steps of: preparing a reconstituted wafer in which defective chips are replaced with good chips; stacking the reconstituted wafer on a base wafer and connecting the wafers; forming through-hole electrodes in the reconstituted wafer; and stacking another reconstituted wafer on the reconstituted wafer including the through-hole electrodes and connecting the wafers.

Furthermore, the method for producing a semiconductor device includes the steps of: preparing a reconstituted wafer in which defective chips are replaced with good chips; forming through-hole electrodes in the reconstituted wafer; and stacking the reconstituted wafer including the through-hole electrodes on a base wafer and connecting the wafers.

### Advantageous Effects of Invention

According to the structure, the semiconductor device producing method that uses a highly-productive W to W bonding process and achieves high yields can be provided.

### BRIEF DESCRIPTION OF DRAWINGS

FIG. 1A illustrates a step (wafer testing and good chip sorting) for removing defective chip areas from a substrate, according to Embodiment 1.

FIG. 1B illustrates a step (formation of a protective film on good chip areas) for removing the defective chip areas from the substrate, according to Embodiment 1.

FIG. 1C illustrates a step (removal and cleaning of the defective chip areas) for removing the defective chip areas from the substrate, according to Embodiment 1.

FIG. 1D illustrates a step (emergence of rough surfaces after the removal of the defective chip areas) for removing the defective chip areas from the substrate, according to Embodiment 1.

FIG. 1E illustrates a step (etching step to the substrate surface in the defective chip areas) for removing the defective chip areas from the substrate, according to Embodiment 1.

FIG. 2A illustrates a step (wafer testing and good chip sorting) for cutting good chips out of a substrate, according to Embodiment 1.

FIG. 2B illustrates a step (formation of a protective film on an entire surface of the substrate) for cutting the good chips out of the substrate, according to Embodiment 1.

FIG. 2C illustrates a step (thinning and mirror-polishing of the substrate) for cutting the good chips out of the substrate, according to Embodiment 1.

FIG. 2D illustrates a step (dicing) for cutting the good chips out of the substrate, according to Embodiment 1.

FIG. 3A illustrates a step (application of adhesive or curable resin) for embedding the good chips in the substrate areas where the defective chips are removed, according to Embodiment 1.

FIG. 3B illustrates a step (alignment of the good chips) for embedding the good chips in the substrate areas where the defective chips are removed, according to Embodiment 1.

FIG. 3C illustrates a step (attachment of the good chips) for embedding the good chips in the substrate areas where the defective chips are removed, according to Embodiment 1.

FIG. 3D illustrates a step (heat curing of the adhesive or curable resin) for embedding the good chips in the substrate areas where the defective chips are removed, according to Embodiment 1.

FIG. 3E illustrates a step (removal of the protective film with the adhesive) for embedding the good chips in the substrate areas where the defective chips are removed, according to Embodiment 1.

FIG. 4 is a flow chart for explaining a method for producing a semiconductor device with reconstituted wafers according to Embodiment 1.

FIG. 5A illustrates a step (formation of bumps) in the method for producing the semiconductor device with the reconstituted wafers, according to Embodiment 1.

FIG. 5B illustrates a step (substrate bonding 1) in the method for producing the semiconductor device with the reconstituted wafers, according to Embodiment 1.

FIG. 5C illustrates a step (thinning and mirror-polishing of the substrate) in the method for producing the semiconductor device with the reconstituted wafers, according to Embodiment 1.

FIG. 5D illustrates a step (formation of TSVs and metal bumps 1) in the method for producing the semiconductor device with the reconstituted wafers, according to Embodiment 1.

FIG. 5E illustrates a step (substrate bonding 2) in the method for producing the semiconductor device with the reconstituted wafers, according to Embodiment 1.

FIG. 5F illustrates a step (formation of TSVs and metal bumps 2) in the method for producing the semiconductor device with the reconstituted wafers, according to Embodiment 1.

FIG. 5G illustrates a step (dicing of the substrate stack) in the method for producing the semiconductor device with the reconstituted wafers, according to Embodiment 1.

FIG. 6A illustrates a step (wafer testing and good chip sorting) in a method for producing a semiconductor device according to Embodiment 2.

FIG. 6B illustrates a step (affixation of a wafer to a glass substrate) in the method for producing the semiconductor device according to Embodiment 2.

FIG. 6C illustrates a step (thinning and mirror-polishing of the wafer) in the method for producing the semiconductor device according to Embodiment 2.

FIG. 6D illustrates a step (formation of a protective film on good chip areas) in the method for producing the semiconductor device according to Embodiment 2.

FIG. 6E illustrates a step (removal of dicing regions of defective chips and device surfaces) in the method for producing the semiconductor device according to Embodiment 2.

FIG. 6F illustrates a step (removal of the defective chips) in the method for producing the semiconductor device according to Embodiment 2.

FIG. 6G illustrates a step (alignment and attachment of the good chips) in the method for producing the semiconductor device according to Embodiment 2.

FIG. 6H illustrates a step (removal of the protective film) in the method for producing the semiconductor device according to Embodiment 2.

FIG. 6I illustrates a step (formation of TSVs and metal bumps) in the method for producing the semiconductor device according to Embodiment 2.

FIG. 6J illustrates a step (wafer bonding) in the method for producing the semiconductor device according to Embodiment 2.

FIG. 6K illustrates a step (detachment of the glass substrate) in the method for producing the semiconductor device according to Embodiment 2.

### DESCRIPTION OF EMBODIMENTS

General W to W bonding processes can provide high productivity due to the wide-range processing capability on a wafer-by-wafer basis; however, the final production yield of the multi-layer chips significantly drops as the percentage of good chips on an original wafer decreases and the number of the stacked wafers increases.

The inventors of the present invention have studied to solve the aforementioned problems in the three dimensional stacking technology when using wafers with defective chips present thereon. Consequently, the inventors found out that even a semiconductor wafer including good chips at a low ratio can be reconstituted to a semiconductor wafer including only good chips by removing only defective chips from the wafer including good chips at a low ratio and placing good chips, which are cut out from another wafer in advance, in areas where the defective chips were removed. The inventors also found out that a stack of the reconstituted wafers or a stack of the reconstituted wafers and another types of wafers, substrates or the like can provide a multi-layer semiconductor wafer or a multi-layer semiconductor device with a highly-maintained yield and productivity. The present invention has been made based on the findings.

In the method for removing defective chips, since the defective chips can be removed by batch processing from a wafer and the good chips are placed in only the areas from which the defective chips were removed, the heat load imposed on the firstly placed chips can be greatly reduced compared with the case of the C to W bonding. In addition, since the wafers can be connected by batch processing, heat load applied to the firstly stacked wafer can be mitigated even if the number of wafers to be stacked increases. In the case where TSVs or bumps are formed after wafer bonding, the TSVs or bumps can be formed by batch processing at the wafer level without lowering productivity. Furthermore, if some selected wafers can be stacked on top of one another so that their defective chip areas align with each other in the stacking direction, the need for removing the defective chips in the areas can be eliminated, thereby improving productivity more efficiently.

The method for producing a reconstituted wafer provided by the following embodiments includes replacing the defective chips on a low-yield wafer with good chips. Even if the low-yield wafers are used, the method for producing a semiconductor device can achieve a high yield using a highly-productive W to W bonding process by reconstituting the low-yield wafers and stacking the reconstituted wafers on top of one another.

The present invention will be described with the embodiments below.

### Embodiment 1

Embodiment 1 will be described below. In Embodiment 1, a multi-layer semiconductor device is obtained by: conducting a KGD (known good die) test at wafer level; fabricating a reconstituted wafer by removing defective chip areas and placing good chips in the areas after the KGD test at the wafer level; stacking the obtained reconstituted wafer on a base wafer; and forming through-hole electrodes and metal bumps.

The semiconductor wafer test method will be first described. The semiconductor wafer test is conducted at wafer level by using general semiconductor wafer test equipment (wafer prober). To identify good chips and defective chips through the wafer test, a circuit and an electrode required for the KGD test need to be formed on chips in advance. For example, Al extraction electrodes, which are made of Al and have the same height, are evenly disposed in a plane on the uppermost part of a wafer on the device side. In circuit design, both Al electrodes electrically conductive with internal circuits and non-conductive Al electrodes are previously formed. The non-conductive Al electrodes are dummy bump Al electrodes formed to reduce the bump height differences or Al electrodes formed to receive dummy bumps for thermal vias. The yields of the wafers in use are 82% to 86%.

Noncontact wafer tests do not require electrodes dedicated to the test. In addition, the wafers can be marked to indicate good chips or defective chips; however, mapping data is more preferable to identify the good chips and defective chips on the wafer.

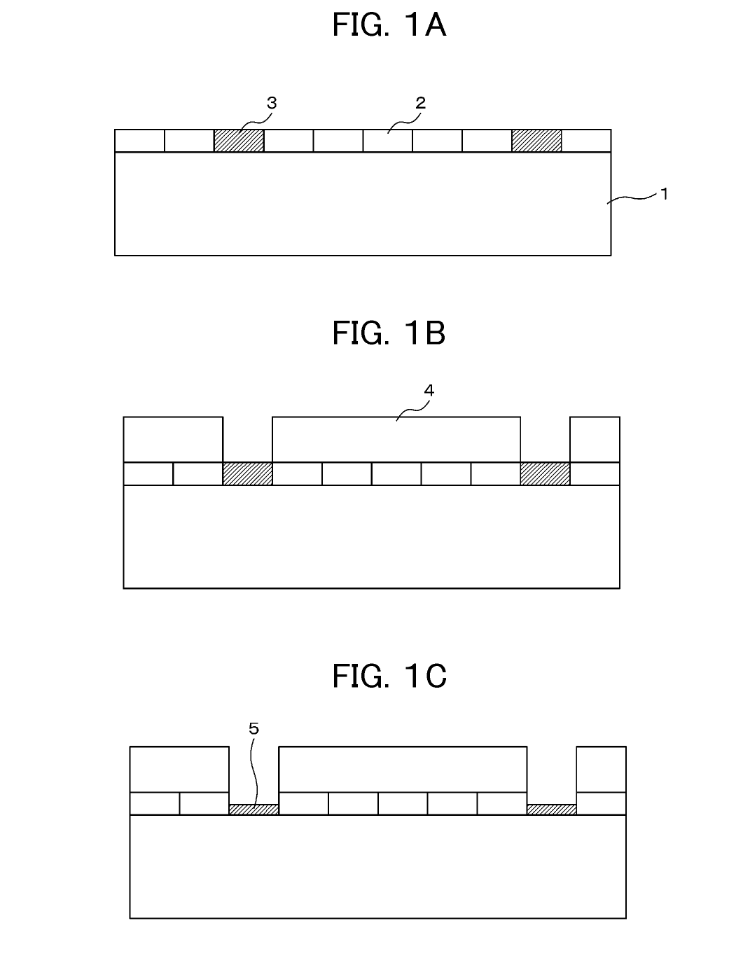

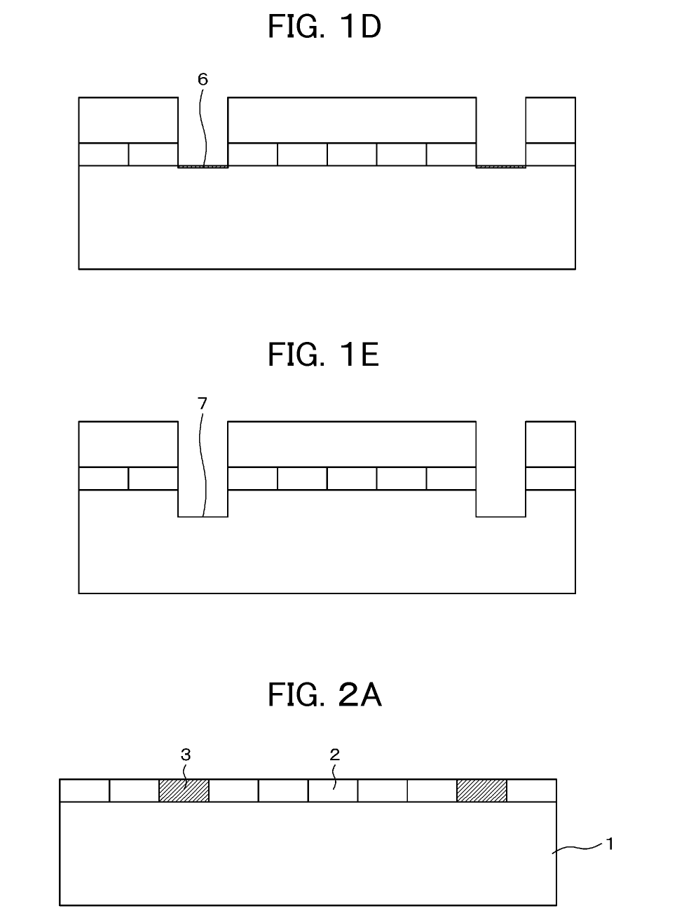

Next, a method for removing defective chips will be described with reference to FIGS. 1A to 1E. After a semiconductor wafer (a Si wafer is used in this embodiment) 1 is subjected to a wafer test to evaluate the quality of chips (FIG. 1A), a resist pattern or a photosensitive resin pattern, as a protective film 4, is formed on the wafer so as to expose defective chip areas 3 and cover good chip areas 2 (FIG. 1B).

The resist or photosensitive resin needs to be thick enough not to harm the good chip areas 2 during removal of the defective chips, preferably about 10 μm to 500 μm in thickness; however, the thickness depends on the material of the resist and resin to be used. A film that is too thick wastes material and is difficult to be removed. The optimal thickness is generally about 30 μm to 200 μm. In this embodiment, a resist pattern is formed on the wafer as a protective film to cover the good chip areas. The resist has a thickness of 100 μm.

In the case where a laminated film of a photosensitive resin and a resist is used, a magnetic film pattern formed on the photosensitive resin enables accurate and efficient placement of the good chips in the defective chip areas 3. The magnetic film used herein is preferably made of generally easily-available magnetic materials mainly containing Fe, Ni, or Co. The pattern shape and thickness of the magnetic film are selected so that the positions of both the good chips and the regions from which the defective chips on the wafer are removed can be detected and the good chips can be handled by the magnetic force. Preferable pattern width is in a range from 100 nm to a few mm, while preferable thickness is in a range from 100 nm to a few μm. A wider and thicker pattern makes it easy to handle the good chips with a collet or the like. However, the too-thick pattern makes the resist uneven, and therefore the pattern should have a thickness that does not affect the flatness of the resist.

The wafer with the protected good chip areas 2 thereon is subjected to ion milling to physically remove the defective chip areas 3, thereby obtaining defective-chip removed areas 5 (FIG. 10). The ion milling process may leave various kinds of foreign matter, but it is removed by wet cleaning using acid or alkali, high pressure cleaning (liquid, gas) or other cleaning methods. The ion milling and cleaning are repeated more than one time to form the defective-chip removed areas 5.

After the defective chip areas are removed, rough Si surfaces appearing at the defective-chip removed areas are removed by isotropic dry etching to obtain smooth Si surfaces. The defective-chip removed areas 5 can be formed by laser rather than ion milling; however, the laser is difficult to use for wafer batch processing and therefore requires a longer time as the number of defective chips to be removed increases. In addition, further concerns about debris and the dimension of Si surface roughness suggest that laser removal is inappropriate.

The depth of the defective-chip removed areas 5 is set to about 120 μm. The preferable depth of the defective-chip removed areas 5 from the device regions is in a range from 1 μm to 500 μm. If the removed areas are too shallow, the surface roughness, in the removed areas, created by ion milling and cleaning adversely affects the embedding operation of the good chips. Formation of removed areas having a depth greater than 200 μm not only takes a longer removal time, but also impairs the wafer strength. The wafer strength impairment is likely to cause wafer breakage when the wafer is applied with heat and pressure during wafer bonding.

On the other hand, regarding the depth of the Si chips on the good chip side, too-thin chips are likely not only to break during handling, but also to warp, and therefore a certain thickness (possibly 30 μm or more) is essential. From the aforementioned viewpoints, the optimal depth of the defective-chip removed areas 5 is from 30 to 200 μm.

The defective chip areas 3 can be removed by ion-milling along the entire thickness through the wafer. It may take more time to penetrate the wafer according to the thickness of the wafer, but precise adjustment of the depth of the chips to be removed is not needed. The penetration of the wafer can be done effectively by thinning the Si wafer 1 in advance and affixing the thin Si wafer 1 to a support substrate such as a glass substrate. The glass substrate or the like can be affixed to either surface with devices or without devices.

If the rough Si surface 6 appears in the defective-chip removed areas 5 after the defective chip areas 3 were removed by ion milling and cleaning (FIG. 1D), for the purpose of preventing wafer strength impairment, the rough Si surface 6 needs to be smoothed by isotropic dry etching or wet etching with HF/HNO₃ to form smooth Si surface 7 (FIG. 1E).

If an SOI (Silicon on Insulator) wafer is used as the Si wafer 1, an SOI layer and an underlying insulating layer are removed by anisotropic dry etching or HF/HNO₃, HF or the like after the device layers in the defective chip areas 3 are removed, thereby obtaining very flat Si surfaces.

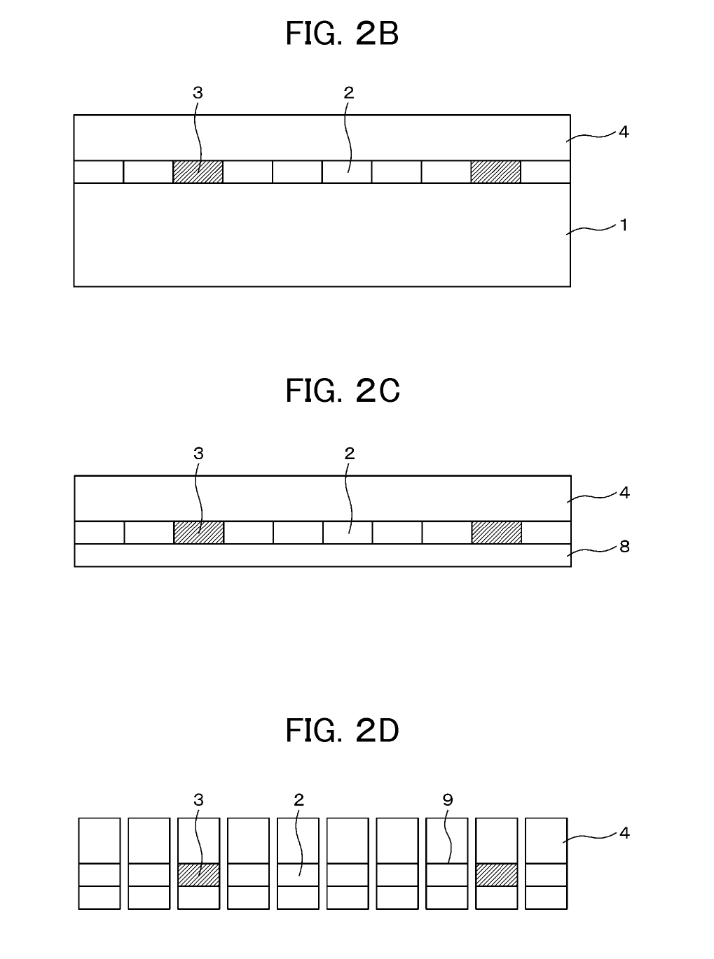

Next, a method for producing good chips will be described with reference to FIGS. 2A to 2D. The processes of producing good chips and the processes of removing defective chips are somewhat different from each other, but have some common processes. First, a wafer is tested at wafer level by a general semiconductor wafer test prober to identify good chips and defective chips (FIG. 2A). A circuit and electrode required for a KGD test need to be formed on chips in advance. There is no need to form test-dedicated electrodes for noncontact KGD tests.

Next, a resist or photosensitive resin, serving as a protective film 4, is applied on the entire Si wafer 1, regardless of good chip areas 2 or defective chip areas 3 (FIG. 2B). The protective film, i.e., a resist or resin, is preferably thinner than the protective film applied to remove the defective chips. This is because the protective film is inevitably made smaller by ion milling and cleaning to remove the defective chips in the removal process of the defective chips; however, in the production process of the good chips, the thickness of the resist or photosensitive resin is not reduced due to absence of ion milling and cleaning process. In Embodiment 1, a protective resist of 80 μm in thickness is applied on the entire surface on the device side of the wafer. Ultimately, the good chips are embedded in the defective-chip removed areas 5, and then the resist film or photosensitive resin film is removed with the film that was subjected to ion milling and cleaning, and therefore it is necessary that the protective films on the good chips are controlled to have the same composition and thickness.

In the case where a magnetic film pattern is formed with a laminated film of photosensitive resin and resist on the photosensitive resin in order to accurately and efficiently place good chips in the defective-chip removed areas 5, the magnetic pattern needs to be made of the same film used to remove the defective chips and needs to have the same shape and thickness as the film.

The wafer with the protective film 4 formed thereon is thinned by a general backgrinding machine, dry-polishing machine and the like, thereby obtaining a thinned Si wafer 8 (FIG. 2C). The thinned Si wafer 8 needs to be a few μm to a few tens of μm thinner than the depth of the defective chips removed areas. This is because adhesive or resin added on the defective-chip removed areas 5 to place the good chips should be taken into consideration. In Embodiment 1, the thinned Si wafer is designed to have a thickness of 100 μm.

The thinned Si wafer 8 is singulated by general dicing processing to provide thinned, singulated good chips 9 (FIG. 2D). The thinned Si wafer 8 can be separated by dicing with a general blade; however, the dicing process is likely to cause chipping on the diced surface. An appropriate method to prevent chipping is forming a dicing pattern with a resist, then performing Si deep trench processing by dry etching, and removing the patterned surface by ion milling and cleaning.

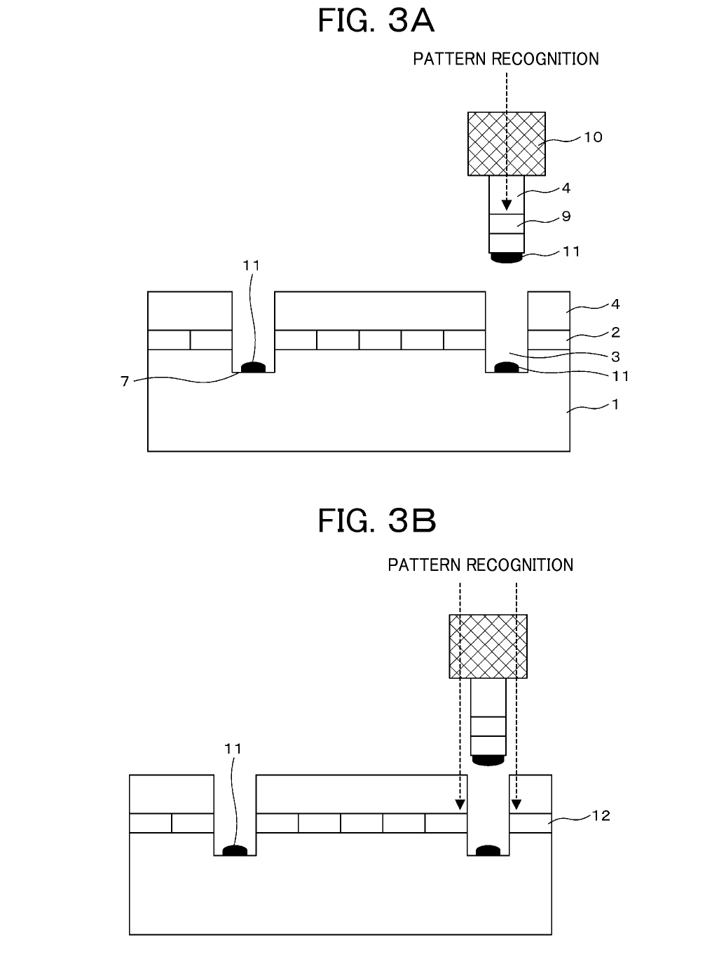

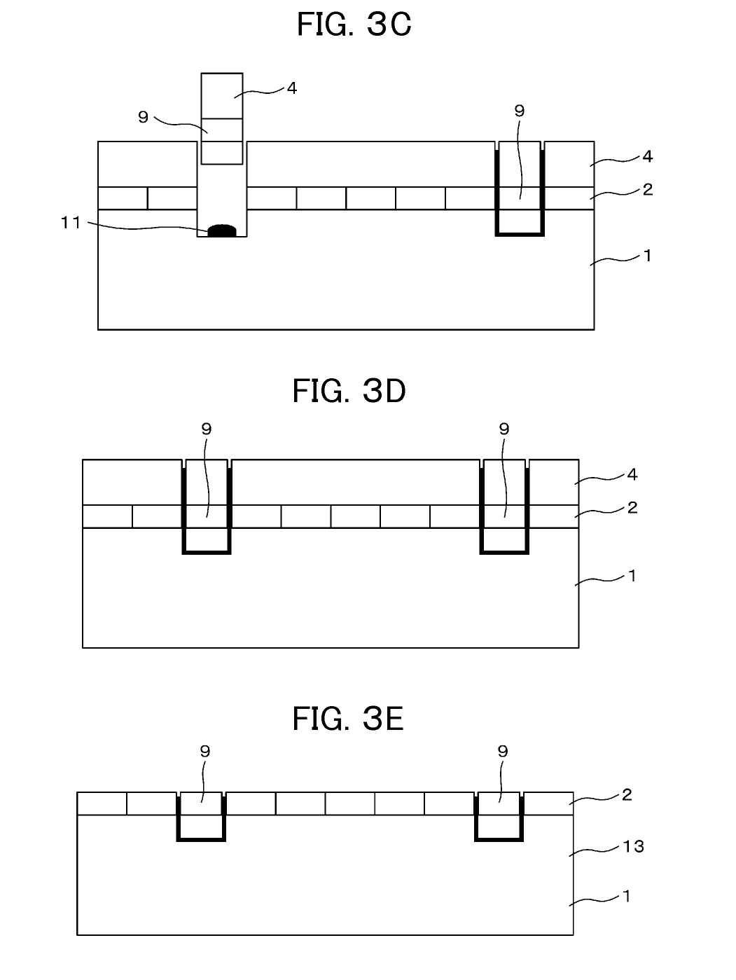

Next, a method for embedding the singulated good chips 9 in the defective-chip removed areas 5 will be described with reference to FIGS. 3A to 3E. A collet 10 holds the singulated good chips 9 from the protective film 4 side (FIG. 3A). Before holding the chips, the collet 10 recognizes the pattern of a singulated good chip 9 to align therewith. If a magnetic pattern is formed on the protective film, a sensor built in the collet 10 detects the magnetic pattern to align the collet with the chip. The magnetic pattern enables alignment within an accuracy of about ±2 μm. In addition, the collet can pick up the chip through the use of the magnetic force of the magnetic pattern. If the magnetic force is not strong enough for the collet to pick up the chip, vacuum suction is also available.

Furthermore, infrared rays (IR) can be also used to align the singulated good chip 9 with the collet 10. The infrared alignment can achieve an alignment accuracy of about ±1 μm.

An adhesive or curable resin 11 of an appropriate amount is applied on either one of the back side of the singulated good chip 9 and the smooth Si surface 7 after the defective chip 3 is removed, or the both (FIG. 3A). In this description, an adhesive is used. If a resist is used as a protective film 4, the chip needs to be adhered at the resist's heat resistance temperature or lower, and therefore the adhesive or curable resin 11 to be used needs to contain a solvent desorbed around 100° C. and to harden at 150° C. or lower. If a photosensitive resin is used as the protective film 4, the adhesive or curable resin 11 to be used needs to have a heat resistance temperature equal to that of the photosensitive resin being used, generally it can be heated to 250° C. or higher.

The proper amount of the adhesive or curable resin 11 to be applied is an amount which fills up the space between the defective-chip removed region 5 and the embedded singulated good chip 9 without gaps. If the adhesive or curable resin is applied too much, the excess overflows from the sides, therefore, care should be taken. The use of the adhesive or curable resin 11 containing a large amount of filler whose thermal expansion coefficient is close to Si reduces problems caused by the difference in thermal expansion coefficient between the adhesive or curable resin 11 and Si. The height difference between the good chips and the embedded good chips preferably ranges within ±5 μm (one-tenth or lower of the metal bump height).

Alignment between the singulated good chip 9 to be embedded and the defective-chip removed region 5 is performed by a camera that recognizes the registration mark of the collet 10 and the pattern 12 (formed in other than defective chip areas 3) on the wafer. If a magnetic pattern is formed on the protective film of each chip, the collet 10 detects the magnetic pattern by the built-in sensor and performs alignment (FIG. 3B) and embeds the chips (FIG. 3C).

Alternatively, alignment can be made by emitting infrared rays (IR) to pass through a singulated good chip 9 and a pattern 12 on the wafer. The back surface of the wafer must be polished to a mirror-smooth state to carry out the alignment. After the singulated good chip 9 is aligned with and embedded in the defective-chip removed region 5, heat is applied to cure the adhesive or resin 11 (FIG. 3D).

At last, a reconstituted wafer 13 containing only good chips, not defective chips, is obtained after the protective film, magnetic pattern and the excessive adhesive or curable resin are removed (FIG. 3E).

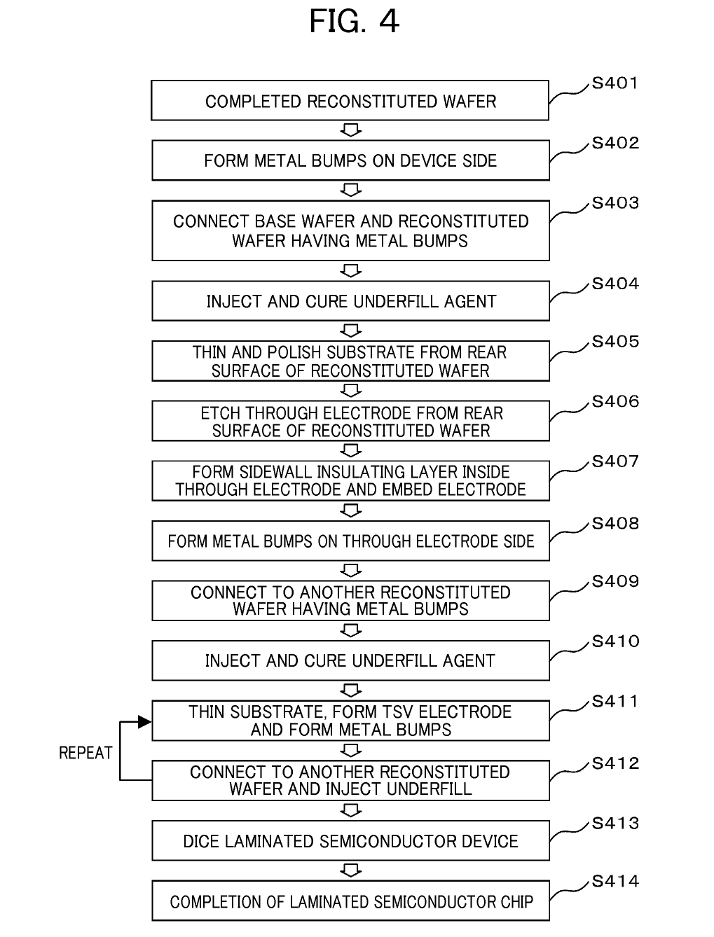

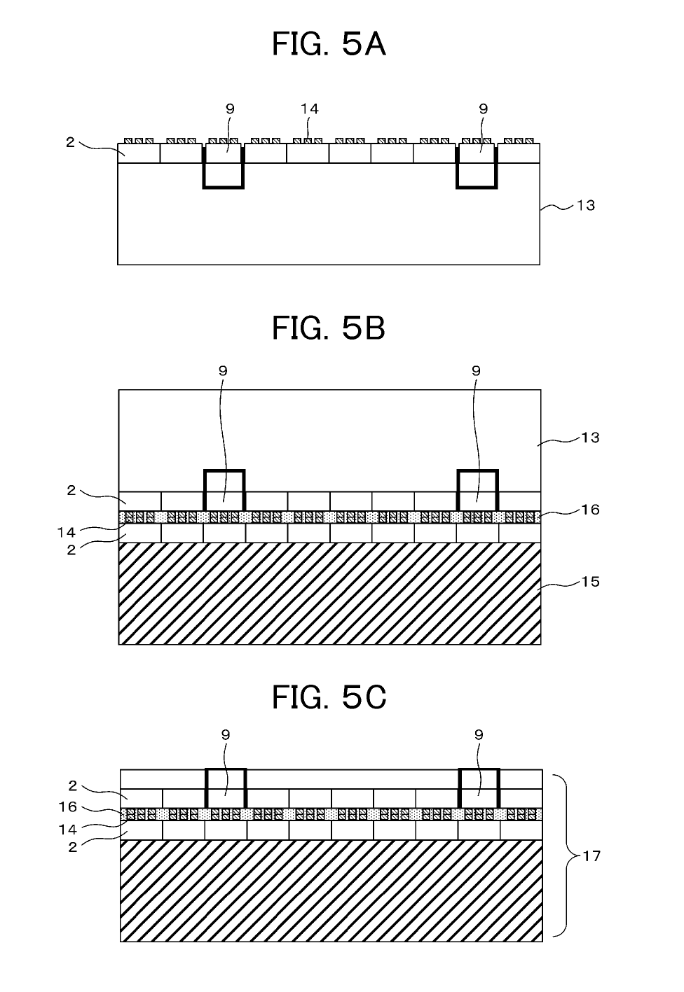

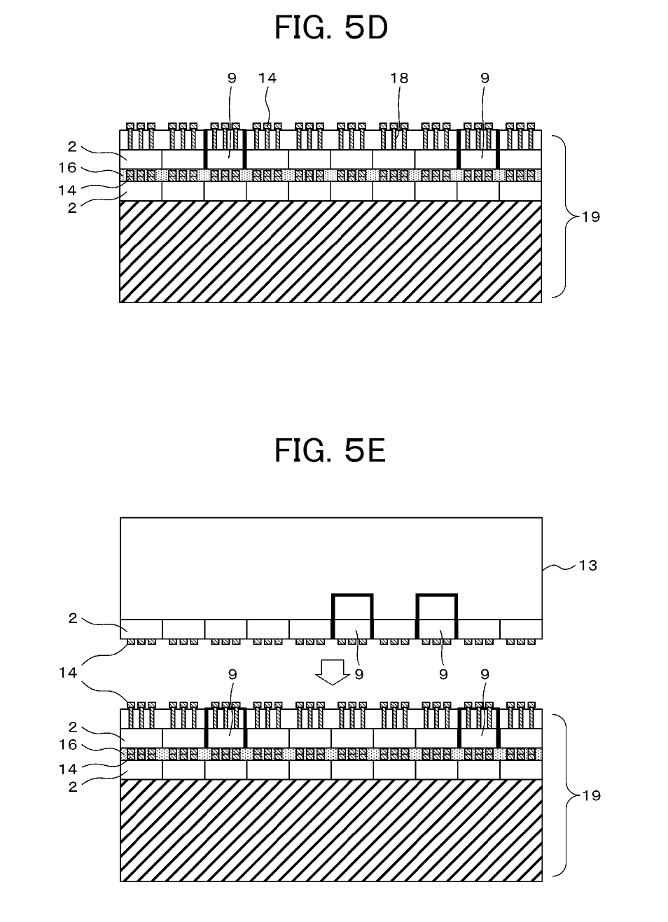

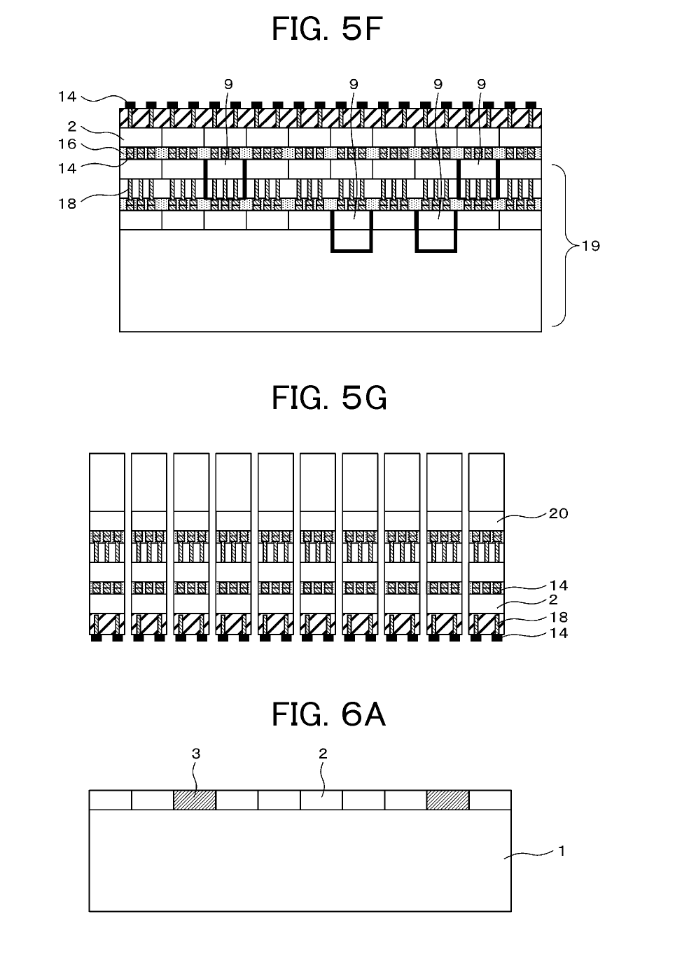

Next, a method for producing a semiconductor device by stacking reconstituted wafers 13 containing only good chips and the thus-obtained semiconductor device will be described using a Via-Last (vias are formed after wafers are stacked on top of one another) case as an example, along the flow chart in FIG. 4, with reference to FIGS. 5A to 5G.

On the device side of a finished reconstituted wafer 13 (S401), metal bumps 14 are firstly formed (S402, FIG. 5A). These metal bumps 14 are arranged in the same layout as that of through-hole electrodes to be formed on the opposite side of the device side so that the metal bumps and the through-hole electrodes align with each other. In this description, the metal bumps 14 are formed on the finished reconstituted wafer; however, it is acceptable to form the metal bumps 14 before the reconstituted wafer 13 is completed. Note that the diameter of the bumps is approximately from 5 to 30 μm (mainly 10 to 20 μm).

The metal bumps 14 can be formed by a general semi-additive process or can be also formed with photosensitive resin. In the case where the bumps are formed with photosensitive resin, for example, after a bump pattern is formed with a photosensitive resin of 8 μm in thickness, TiN and Cu are deposited as a seed metal and the seed metal is plated with Cu to form bumps. The metal bumps can be made of typical bump materials, for example, soldering materials such as SnAg or noble metal such as Au.

Subsequent to the bump pattern formation, the formation of the metal bumps 14 with photosensitive resin is followed by seed metal deposition, bump formation by sputtering, vapor deposition or plating and CMP of the bump surface and photosensitive resin surface. An advantage of the metal bumps 14 formed with the photosensitive resin is the omission of an underfill agent injection after wafer bonding because the resin regions present around the bumps are connected with each other to bond the wafers. To achieve the wafer bonding, the top surface of the wafer is subjected to cutting work by a tool bit to flatten the irregular height of the bumps and photosensitive resin. Bonding wafers with such highly-planarized bumps and photosensitive resin provide a highly reliable multi-layer wafer. Note that the height of the cut bumps is 6 μm.

Next, the reconstituted wafer 13 with the metal bumps 14 formed thereon is aligned with a base wafer 15 fabricated separately, and they are then bonded to each other (S403). The base wafer 15 has metal bumps 14 formed in the same layout as those formed on the device side of the reconstituted wafer 13. The aligned wafers are applied with heat and a predetermined pressure so as to connect their metal bumps 14. Obviously, the base wafer includes a plurality of good chips. In the case where the photosensitive resin is not used, an underfill agent 16 is injected between the bonded wafers in a vacuum and then cured by heat to enhance the wafer bonding reliability (S404, FIG. 5B). The wafers using the photosensitive resin do not require the underfill agent or the like to be injected therebetween because, as described above, the photosensitive resin films on both wafers adhere to each other.

After the reconstituted wafer 13 is stacked on the base wafer 15, the substrate of the reconstituted wafer 13 is thinned and mirror-polished from the back (rear) surface (S405, FIG. 5C). The thickness of the reconstituted wafer at this moment is set to 30 μm. On the mirror-finished surface of the thinned wafer stack 17, hard mask deposition for through-hole electrodes (through electrodes), lithographic patterning, Si deep trench processing by dry etching are performed to form through-hole electrodes 18 (S406). Deposited inside the through-hole electrodes (through electrodes) 18 is a CVD oxide film, serving as a sidewall insulating film, deposited at a low temperature. A CVD oxide film on the bottom of the through-hole electrodes, an element isolation insulating film, an interlayer insulating film and the like are all removed by dry etching to expose the electrode inside the device side wafer. The electrodes on the device side are Ta/Cu electrodes. Subsequently, a seed layer (Ta/Cu) is deposited on the inner wall of the through-hole electrodes 18 by a sputtering machine, and then the through-hole electrodes 18 are all filled with Cu by Cu-plating. At last, the edges of the electrodes are flattened through CMP, thereby obtaining through-hole electrodes 18 (S407). Note that the seed layer can be a TiN/Cu seed layer.

Next, metal bumps 14 are formed on ends of the through-hole electrodes (through electrodes) by semi-additive processing after depositing seed metal films on the ends of the through-hole electrodes 18 by sputtering (S408), thereby obtaining a multi-layer semiconductor device 19 (FIG. 5D). Alternatively, the metal bumps can be formed with photosensitive resin. This multi-layer semiconductor device 19 is aligned with another reconstituted wafer 13 with metal bumps formed on the device side so that the metal bumps 14 on the semiconductor device 19 align with the metal bumps on the reconstituted wafer 13 (FIG. 5E), and the wafers are bonded with application of appropriate heat and pressure (S409). Instead of the reconstituted wafer 13 prepared separately, a high-yield semiconductor wafer can be also bonded.

After the bonding process, a plurality of reconstituted wafers 13 can be stacked through the above-described steps (S410 to S412) (FIG. 5F). In this description, two reconstituted wafers are stacked in addition to the base wafer, resulting in a three-layer semiconductor device. The multi-layer (laminated) semiconductor device 19 including the desired number of layers is cut in a dicing process (S413) into complete multi-layer (laminated) semiconductor chips 20 (S414, FIG. 5G).

Six-layer semiconductor devices each including five reconstituted wafers stacked on top of one another were prepared and referred to as A. All of the six-layer semiconductor devices A were subjected to an operational reliability test in which the devices are run repeatedly in a temperature cycle varying from −25° C. to 125° C. The resultant yield obtained from the device operational reliability test was 93%. Possible reasons that the resultant yield is lower than 100% even though the devices were made by stacking the reconstituted wafers with only good chips are: 1) breakage of good chips in the step of removing defective chips; 2) misalignment of the good chips in the placement step; and 3) faulty connections between bumps during wafer bonding.

The estimated yield of five-layer semiconductor devices fabricated by stacking wafers each having a yield of 82% to 86% in a conventional method is 37% to 47%. If the faulty connections between bumps during wafer bonding are taken into account, the yield of the conventional semiconductor devices falls ½ to ⅓ of the semiconductor devices according to Embodiment 1. The yield difference is expected to be greater in the case of more than five wafers stacked to form semiconductor devices.

In the above described stacking method, every reconstituted wafer bonded on top of one another includes good chips fixedly embedded in defective-chip removed areas 5; however, it is possible to bond a wafer having defective-chip removed areas 5 without good chips embedded therein to a wafer, which is opposed to the wafer, having good chips connected thereto in advance. Defective chips are removed from the wafers and good chips are attached at positions corresponding to the defective chip areas of the opposed wafers by a C to W bonding process, and then these wafers are bonded. This method has a disadvantage in that, if the wafers to be bonded to each other have defective chip areas at the same positions, good chips cannot be attached in those areas.

As described above, Embodiment 1 can provide a semiconductor device producing method that uses a highly-productive W to W bonding process and achieves high yields. In addition, a method for producing a high yield reconstituted wafer can be also provided.

### Embodiment 2

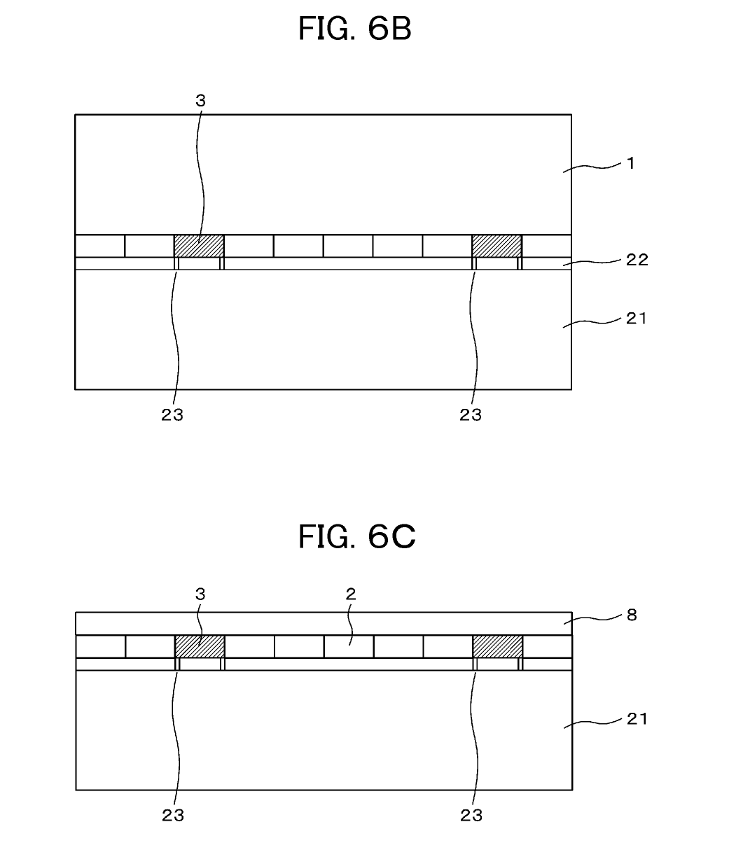

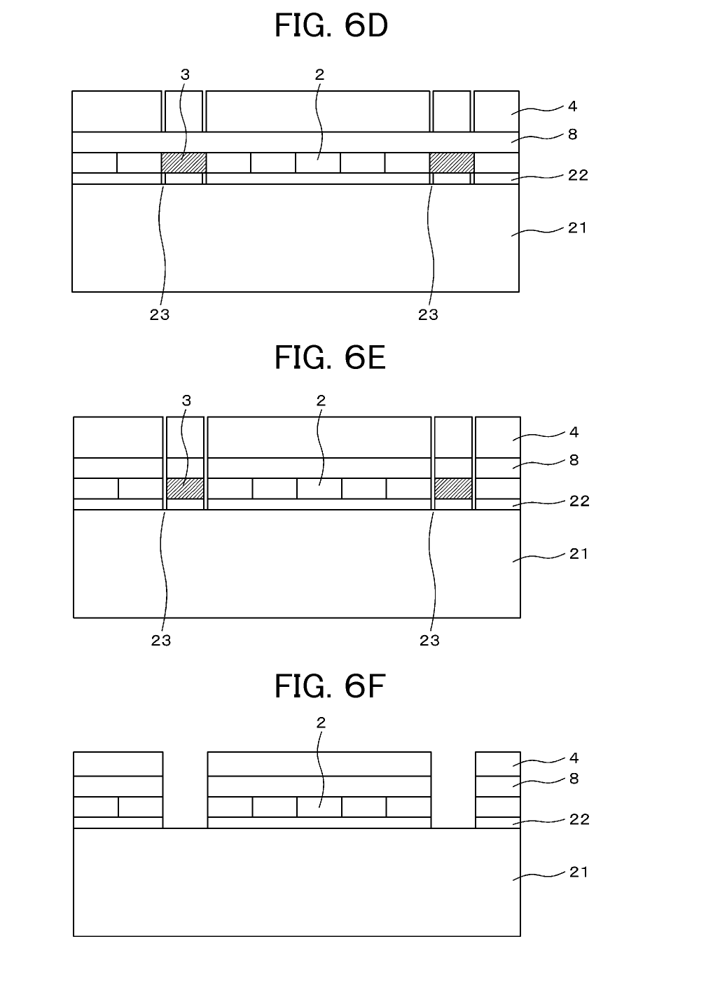

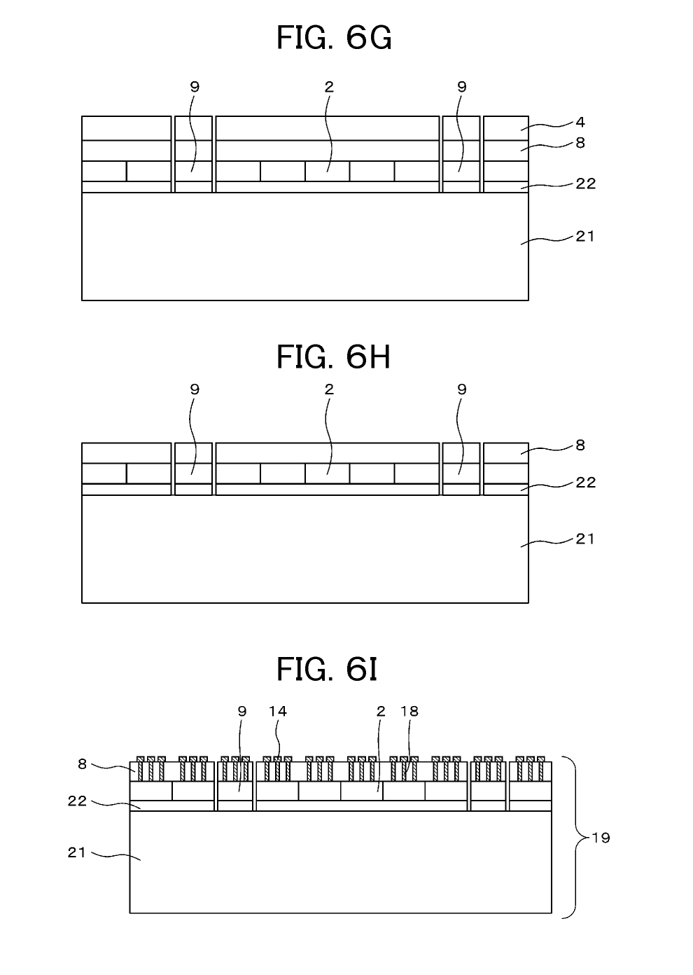

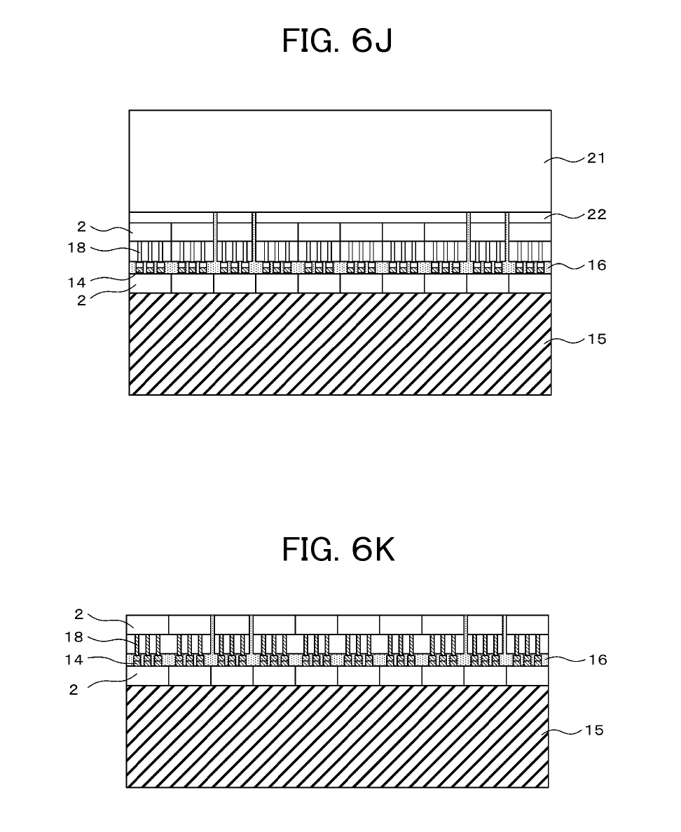

Embodiment 2 will be described with reference to FIGS. 6A to 6K. Note that the matters stated in Embodiment 1, but not in Embodiment 2, are to be applied to Embodiment 2 unless otherwise specified.

FIGS. 6A to 6K illustrate steps of the method for producing semiconductor devices according to Embodiment 2 and describe Embodiment 2 in which a reconstituted wafer supported by a glass substrate is fabricated. The reconstituted wafer is obtained by conducting a KGD test at wafer level, affixing a wafer on a glass substrate with the device surface facing the glass substrate, thinning and mirror-polishing the wafer, removing defective chip areas, and placing good chips in the areas. The differences from Embodiment 1 are in that through-hole electrodes and metal bumps are formed prior to wafer bonding and the glass support substrate is detached after wafer bonding.

As with Embodiment 1, Al extraction electrodes, which are made of Al and have the same height, are evenly disposed in a plane on the uppermost part of a wafer on the device side. In circuit design, both Al electrodes electrically conductive with internal circuits and non-conductive Al electrodes are previously formed. The non-conductive Al electrodes are dummy bump Al electrodes formed to reduce the bump height differences or Al electrodes formed to receive dummy bumps for thermal vias.

As the result of wafer testing and good chip sorting (FIG. 6A), the yields of the wafers in use are 82% to 86%, which are the same as Embodiment 1.

First, a method for removing defective chip areas will be described. Subsequent to the wafer testing to identify good chips, a wafer 1 is affixed on a glass substrate 21 so that its device surface faces the glass substrate (FIG. 6B). An UV release adhesive or UV release tape 22, or a thermoplastic adhesive is used for affixation.

In this description, a tape, which is releasable by ultraviolet rays, is used. The tape has cutoff lines 23 so that only the tape portions under the defective chip areas can be peeled off later.

Next, the wafer is thinned by a general backgrinding machine and mirror-polished by a general dry polishing machine (FIG. 6C). The thickness of the thinned Si wafer 8 is reduced to 30 μm.

Then, a protective film 4 having cutoff lines at dicing regions, which are around defective chip areas 3 to be diced, is formed (FIG. 6D). Subsequent to removal of only the dicing regions of the defective chip areas 3 by Si etching, the device areas are repeatedly subjected to ion milling and cleaning to physically remove the dicing regions of the defective chip areas 3 (FIG. 6E). The tape 22 by which the device surfaces in the defective chip areas are fixed is irradiated with ultraviolet rays from the glass substrate 21 side to remove the defective chips together with the tape (FIG. 6F).

Next, a method for producing good chips will be described. The method is almost the same as that in Embodiment 1, but different in that, a tape, which is the same in quality and thickness as the tape used to affix the wafer to the glass substrate, is placed on the device surface and a protective film is formed on the opposite side to the device surface. The thickness of the good chip at this stage is 30 μm.

The above-described singulated good chips 9 are aligned with and placed in the regions where the defective chips are removed (FIG. 6G). The alignment can be easily made because the device pattern can be seen from the glass substrate 21 side.

After the good chips 9 are affixed to the defective chip areas, the protective film 4 is removed to obtain a reconstituted wafer affixed on the glass substrate 21 (FIG. 6H). Through-hole electrodes 18 and metal bumps 14 are formed on the reconstituted wafer to obtain a multi-layer semiconductor device 19 affixed on the glass substrate 21 (FIG. 6I).

Next, a base wafer 15, fabricated separately, with metal bumps and the multi-layer semiconductor device 19 affixed on the glass substrate 21 are bonded together, and then an underfill agent 16 is injected and cured by heat to enhance bonding reliability (FIG. 6J). Needless to say, the reconstituted wafer (semiconductor wafer without a glass substrate) having the structure shown in Embodiment 1 can be used as the separately fabricated base wafer 15 having the metal bumps.

Then, ultraviolet rays are applied to the multi-layer semiconductor device 19 from the glass substrate 21 side to remove the glass substrate 21 together with the tape 22 to expose the device surface (FIG. 6K). Metal bumps are formed on the device surface, as shown in FIG. 5D, and another multi-layer semiconductor device 19 affixed on a glass substrate is further bonded, thereby obtaining a multi-layer wafer.

Through the same steps as described above, five reconstituted wafers are stacked in addition to the base wafer, resulting in a six-layer semiconductor device. This multi-layer semiconductor device is subjected to a dicing step to cut into multi-layer semiconductor chips, or so-called multi-layer semiconductor devices. The thus-obtained multi-layer semiconductor devices are referred to as B.

All of the obtained multi-layer semiconductor devices B were subjected to an operational reliability test in which the devices are run repeatedly in a temperature cycle varying from −25° C. to 125° C. The resultant yield obtained from the device operational reliability test was 95%. Possible reasons that the resultant yield is lower than 100% even though the devices were made by stacking the reconstituted wafer with only good chips are: 1) breakage of good chips in the step of removing defective chips; 2) misalignment of the good chips in the placement step; and 3) faulty connections between bumps during wafer bonding.

The estimated yield of five-layer semiconductor devices fabricated by stacking wafers each having a yield of 82% to 86% in a conventional method is 37% to 47%. If the faulty connections between bumps during wafer bonding are taken into account, the yield of the conventional semiconductor devices falls ½ to ⅓ of the semiconductor devices according to Embodiment 2. The yield difference is expected to be greater in the case of more than five wafers stacked to form semiconductor devices.

As described above, Embodiment 2 can provide a semiconductor device producing method that uses a highly-productive W to W bonding process and achieves high yields. In addition, a method for producing a high yield reconstituted wafer can be provided. Furthermore, the use of the glass substrate eliminates the need for accurate adjustment of the depth of the defective chips to be removed, thereby improving the reproducibility of the process.

### REFERENCE SIGNS LIST

1: Si wafer;
2: Good chip area;
3: Defective chip area;
4: Protective film;
5: Defective-Chip removed area;
6: Rough Si surface;
7: Smooth Si surface;
8: Thinned Si wafer;
9: Singulated good chip;
10: Collet;
11: Adhesive or curable agent;
12: Pattern on the wafer side;
13: Reconstituted wafer;
14: Metal bump;
15: Base wafer;
16: Underfill agent;
17: Multi-Layer wafer;
18: Through-Hole electrode;
19: Multi-Layer semiconductor device;
20: Multi-Layer semiconductor chip;
21: Glass substrate;
22: Adhesive or tape;
23: Cutoff line

1. A method for producing a reconstituted wafer comprising the steps of:
preparing a semiconductor wafer with a plurality of semiconductor chips formed thereon;
conducting a test on the semiconductor wafer to identify good chips;
removing defective chip areas including defective chips from the semiconductor wafer; and
placing good chips extracted from another semiconductor wafer in the removed defective chip areas.

2. A method for producing a semiconductor device comprising the steps of:
preparing a reconstituted wafer fabricated by the method for producing a reconstituted wafer cited in claim 1; and
stacking the reconstituted wafer on a semiconductor wafer or substrate.

3. The method for producing a semiconductor device according to claim 2, comprising the step of:
forming a metal pad or a metal bump on an end of an electrode formed on an element area side of the reconstituted wafer and the semiconductor wafer or substrate.

4. The method for producing a semiconductor device according to claim 3, comprising the step of:
stacking the metal pad or metal bump formed on the reconstituted wafer and the metal pad or metal bump formed on the semiconductor wafer or substrate and connecting them.

5. The method for producing a semiconductor device according to claim 4, further comprising the steps of:
thinning either one of the reconstituted wafer, or the semiconductor wafer or substrate disposed on an upper side or a lower side of the semiconductor device; and
forming a through-hole electrode in the thinned reconstituted wafer, or the semiconductor wafer or substrate.

6. The method for producing a semiconductor device according to claim 5, comprising the step of:
forming a metal pad or a metal bump on the through-hole electrode.

7. The method for producing a semiconductor device according to claim 6, further comprising the step of:
stacking a plurality of other reconstituted wafers, or a plurality of other semiconductor wafers or other substrates on the metal pad or metal bump formed on the through-hole electrode.

8. The method for producing a semiconductor device according to claim 2, comprising the step of:
singulating the stacked reconstituted wafers.

9. A method for producing a semiconductor device comprising the steps of:
preparing a reconstituted wafer in which a defective chip is replaced with a good chip;
stacking the reconstituted wafer on a base wafer and connecting the wafers;
forming a through-hole electrode in the reconstituted wafer; and
stacking another reconstituted wafer on the reconstituted wafer with the through-hole electrode and connecting the wafers.

10. The method for producing a semiconductor device according to claim 9, comprising the step of:
injecting an underfill agent between the reconstituted wafer and the other reconstituted wafer.

11. The method for producing a semiconductor device according to claim 9, wherein the base wafer is a semiconductor wafer including a plurality of good chips.

12. The method for producing a semiconductor device according to claim 9, further comprising the step of:
singulating the reconstituted wafer and the other reconstituted wafer stacked thereon with the base wafer.

13. A method for producing a semiconductor device comprising the steps of:
preparing a reconstituted wafer in which a defective chip is replaced with a good chip;
forming a through-hole electrode in the reconstituted wafer; and
stacking the reconstituted wafer with the through-hole electrode on a base wafer and connecting the wafers.

14. The method for producing a semiconductor device according to claim 13, wherein
the reconstituted wafer is supported on a glass substrate.

15. The method for producing a semiconductor device according to claim 14, further comprising the steps of:
detaching the glass substrate from the reconstituted wafer; and
singulating the reconstituted wafer stacked on the base wafer after the detachment.
